(19) United States
(12) Patent Application Publication
(10) Pub. No.: US 2025/0265006 A1
(43) Pub. Date: Aug. 21, 2025

(54) MEMORY STORAGE APPARATUS AND METHOD FOR OPERATING MEMORY STORAGE APPARATUS

(71) Applicant: Winbond Electronics Corp., Taichung City (TW)

(72) Inventor: Jen-Chuan Cheng, Hsinchu (TW)

(73) Assignee: Winbond Electronics Corp., Taichung City (TW)

(21) Appl. No.: 19/019,543

(22) Filed: Jan. 14, 2025

(30) Foreign Application Priority Data
Feb. 19, 2024 (TW) 113105687

(51) Int. Cl. G06F 3/06

(52) U.S. Cl. CPC G06F 3/0652; G06F 3/0604; G06F 3/0673

(57) ABSTRACT

A memory storage apparatus, including a memory array and a controller circuit, is provided. The memory array is configured to store data. The controller circuit is coupled to the memory array. The controller circuit configured to receive a reset signal and a trigger signal. The controller circuit performs a reset operation according to the reset signal. The controller circuit maintains a power supply to the memory array according to the trigger signal during a reset period.

### CROSS-REFERENCE TO RELATED APPLICATION

This application claims the priority benefit of Taiwan application serial no. 113105687, filed on Feb. 19, 2024. The entirety of the above-mentioned patent application is hereby incorporated by reference herein and made a part of this specification.

### TECHNICAL FIELD

This disclosure relates to an electronic device and a method for operating the same, and in particular to a memory storage apparatus and a method for operating the memory storage apparatus.

### DESCRIPTION OF RELATED ART

Taking the volatile memory as an example, the data stored in the memory storage apparatus disappears during a power outage. For instance, a dynamic random-access memory (DRAM) cannot retain stored data after reset. However, in some applications, users may want to retain the stored data after the DRAM is reset to meet the requirement of a quick boot.

### SUMMARY

This disclosure provides a memory storage apparatus and a method for operating the same, which can perform reset without power outage and maintain the accuracy of stored data after reset.

The memory storage apparatus of this disclosure includes a memory array and a controller circuit. The memory array is configured to store data. The controller circuit is coupled to the memory array. The controller circuit is configured to receive a reset signal and a trigger signal. The controller circuit performs a reset operation according to the reset signal. The controller circuit maintains a power supply to the memory array according to the trigger signal during a reset period.

The method for operating the memory storage apparatus of this disclosure includes: receiving a reset signal and a trigger signal; performing a reset operation according to the reset signal; and maintaining a power supply to a memory array according to the trigger signal during a reset period.

In order to make the above-mentioned features and advantages of this disclosure more obvious and easy to understand, embodiments are given below and described in detail with reference to the accompanying drawings.

### BRIEF DESCRIPTION OF THE DRAWINGS

FIG. 1 is a schematic block diagram of a memory storage apparatus of an embodiment of this disclosure.

FIG. 2 is a schematic waveform diagram of a trigger signal of the embodiment of FIG. 1.

FIG. 3 is a schematic waveform diagram of a trigger signal of another embodiment of this disclosure.

FIG. 4 is a schematic block diagram of a memory storage apparatus of an embodiment of this disclosure.

FIG. 5 is a schematic waveform diagram of a reset signal and a reference signal of an embodiment of this disclosure.

FIG. 6 is a flowchart of steps of a method for operating a memory storage apparatus of an embodiment of this disclosure.

FIG. 7 is a flowchart of steps of a method for operating a memory storage apparatus of another embodiment of this disclosure.

### DETAILED DESCRIPTION OF DISCLOSED EMBODIMENTS

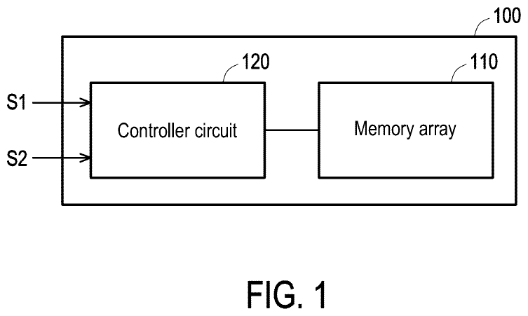

FIG. 1 is a schematic block diagram of a memory storage apparatus of an embodiment of this disclosure. Please refer to FIG. 1. A memory storage apparatus 100 includes a memory array 110 and a controller circuit 120. The controller circuit 120 is coupled to the memory array 110. The controller circuit 120 is configured to receive a reset signal S1 and a trigger signal S2. The controller circuit 120 performs a reset operation according to the reset signal S1. The controller circuit maintains a power supply to the memory array 110 according to the trigger signal S2 during a reset period.

In this embodiment, the memory storage apparatus 100 is, for example, a dynamic random-access memory (DRAM). Through maintaining the power supply to the memory array 110 during the reset period, the DRAM may perform reset without power outage and maintain the accuracy of internally stored data after reset.

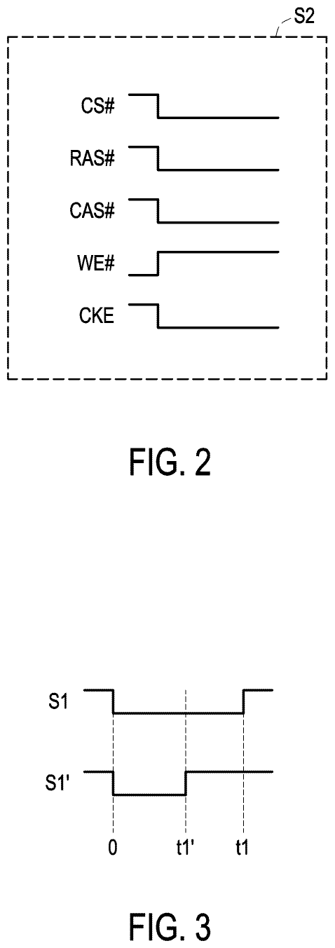

FIG. 2 is a schematic waveform diagram of a trigger signal of the embodiment of FIG. 1. Please refer to FIG. 1 and FIG. 2. The trigger signal S2 of the embodiment of FIG. 1 may be a combination of external signals input to pins of the memory storage apparatus 100. The combination of the external signals includes signal type or voltage level. Specifically, the memory storage apparatus 100 is, for example, a DRAM chip. The external signals input to the pins of the DRAM chip include signals such as CS #, RAS #, CAS #, WE #, and CKE, wherein CS # is a chip selection signal, RAS # is a row address signal, CAS # is a column address signal, WE # is a write enable signal, and CKE is a reference signal. Through the different types of signal combinations and/or the high and low voltage levels, the controller circuit 120 may be triggered to determine whether to maintain the power supply to the memory array 110 during the reset period.

In FIG. 2, the numbers, types, combinations, and voltage levels of the external signals are only used for demonstrative explanation and are not intended to limit this disclosure. In other embodiments, the external signals of different numbers, types, combinations, and voltage levels may also be used as the trigger signal S2.

FIG. 3 is a schematic waveform diagram of a trigger signal of another embodiment of this disclosure. Please refer to FIG. 1 and FIG. 3. The reset signal S1 of the embodiment of FIG. 1 may also be used as the trigger signal S2. The time length of the reset signal S1 may be used to determine whether to trigger the operation of the controller circuit 120 maintaining the power supply to the memory array 110 during the reset period. Specifically, in FIG. 3, reset signals S1 and S1′ have a first level (low level) and a second level (high level). Compared with the reset signal S1′, the time length of the first level of the reset signal S1 is longer. The reset signal S1 with the longer time length may be used as the trigger signal S2 to trigger the operation of maintaining the power supply. That is to say, the time length of the first level of the reset signal S1′ may be used as a threshold t1′, and the reset signal S1 with the time length greater than the threshold t1′ may be used as the trigger signal S2.

On the contrary, in an embodiment, the reset signal S1′ with the shorter time length may also be used as the trigger signal S2 to trigger the operation of maintaining the power supply. In this example, the time length of the first level of the reset signal S1 may be used as a threshold t1, and the reset signal S1′ with the time length less than the threshold t1 may be used as the trigger signal S2.

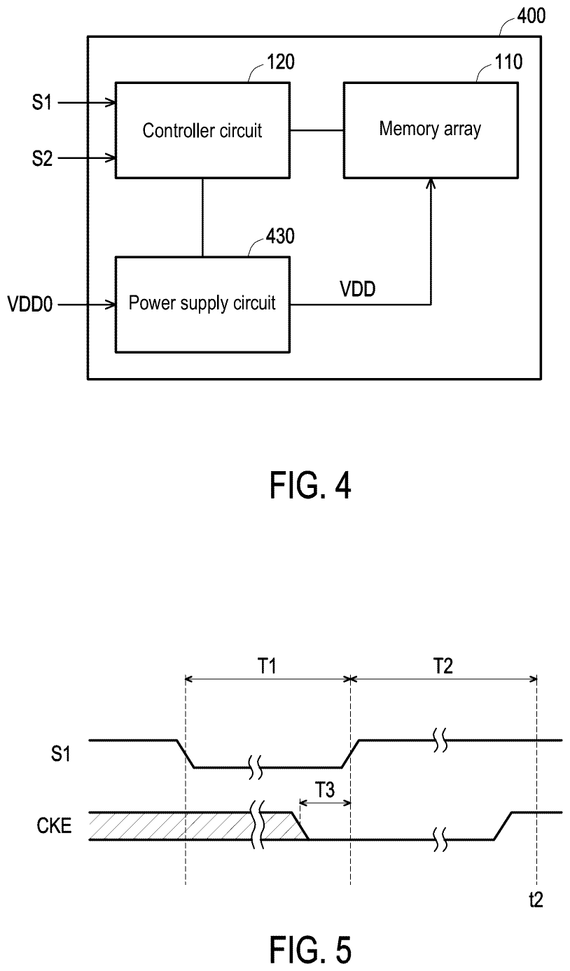

FIG. 4 is a schematic block diagram of a memory storage apparatus of an embodiment of this disclosure. Please refer to FIG. 4. A memory storage apparatus 400 of this embodiment further includes a power supply circuit 430. The power supply circuit 430 is coupled to the memory array 110 and the controller circuit 120. The power supply circuit 430 may be configured to receive an external power supply VDDO and generate a power supply VDD according to the external power supply VDDO. The power supply VDD may provide a power supply required for each circuit block inside the memory storage apparatus 400 to execute various operations.

The power supply circuit 430 provides the power supply VDD to the memory array 110 during the reset period, wherein the power supply circuit 430 may determine whether to maintain the power supply to the memory array 110, that is, to continuously provide the power supply VDD to the memory array 110 during the reset period according to a command of the controller circuit 120 to ensure that the memory array 110 can maintain the accuracy of the internally stored data after reset.

In an embodiment, the controller circuit 120 may include a reset circuit block and a self-refresh circuit block for executing the reset operation and a self-refresh operation, respectively. The reset circuit block and the self-refresh circuit block may be implemented as logic circuits on an integrated circuit. For instance, the following hardware may implement the related functions of the reset circuit block and the self-refresh circuit block: one or more controllers, microcontrollers, microprocessors, application-specific integrated circuits (ASIC), digital signal processors (DSP), field programmable gate arrays (FPGA), central processing units (CPU), and/or various logic blocks, modules, and circuits in other processing units. The related functions of the reset circuit block and the self-refresh circuit block may be implemented in hardware circuits such as various logic blocks, modules, and circuits in the integrated circuits through using a hardware description language (HDL) (for example, Verilog HDL or very high-speed integrated circuit (VHSIC) hardware description language (VHDL), or other suitable programming language. In addition, sufficient teachings, suggestions, and implementation instructions of the memory array 110, the controller circuit 120, and the power supply circuit 430 may be obtained by referring to common knowledge in the related art.

FIG. 5 is a schematic waveform diagram of a reset signal and a reference signal of an embodiment of this disclosure. Please refer to FIG. 1 and FIG. 5. After the memory storage apparatus 100 is powered up, the controller circuit 120 executes the reset operation and the self-refresh operation according to the reset signal S1 and the reference signal CKE.

Specifically, first, the controller circuit 120 performs the reset operation according to the reset signal S1, and maintains the power supply to the memory array 110 according to the trigger signal S2 during a reset period T1. In this embodiment, the controller circuit 120 performs the self-refresh operation on the memory array 110 after the reset period T1 is greater than a preset time length. For instance, the controller circuit 120 executes the self-refresh operation after executing the reset operation for more than 100 nanoseconds, so that the operation of the memory storage apparatus 100 complies with standard specifications.

Then, after executing the reset operation, the controller circuit 120 performs the self-refresh operation on the memory array 110 during a self-refresh period T2. In this embodiment, the controller circuit 120 stops the self-refresh operation according to the reference signal CKE. For instance, after the reference signal CKE remains at a low level for a period of time T3, the controller circuit 120 performs the self-refresh operation on the memory array 110 until the reference signal CKE changes from the low level to a high level (time t2). The memory storage apparatus 100 exits the self-refresh mode, and the controller circuit 120 stops performing the self-refresh operation on the memory array 110.

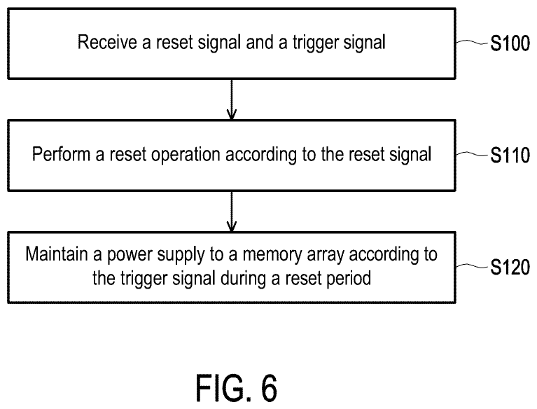

FIG. 6 is a flowchart of steps of a method for operating a memory storage apparatus of an embodiment of this disclosure. Please refer to FIG. 1 and FIG. 6. The method for operating the memory storage apparatus of this embodiment is at least applicable to the memory storage apparatus 100 of FIG. 1, but this disclosure is not limited thereto.

Taking the memory storage apparatus 100 of FIG. 1 as an example, in Step S100, the controller circuit 120 receives the reset signal S1 and the trigger signal S2. In Step S110, the controller circuit 120 performs the reset operation according to the reset signal S1. In Step S120, the controller circuit 120 maintains the power supply to the memory array 110 according to the trigger signal S2 during the reset period T1.

In addition, sufficient teachings, suggestions, and implementation instructions of the method for operating the memory storage apparatus of this embodiment may be obtained from the description of the embodiments in FIG. 1 to FIG. 5, and thus will not be described again.

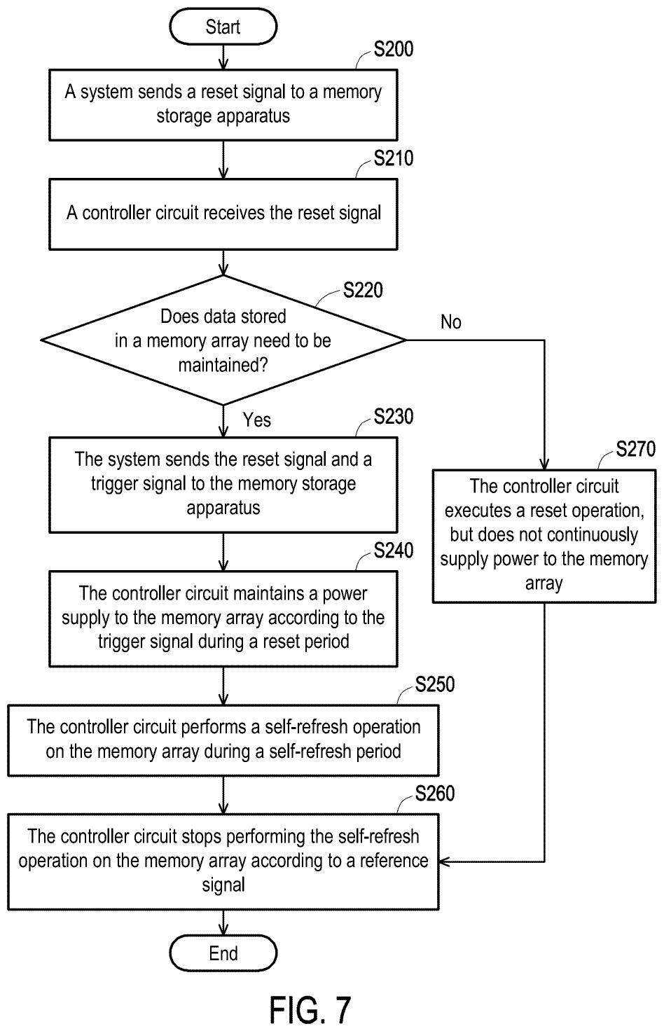

FIG. 7 is a flowchart of steps of a method for operating a memory storage apparatus of another embodiment of this disclosure. Please refer to FIG. 1 and FIG. 7. The method for operating the memory storage apparatus of this embodiment is at least applicable to the memory storage apparatus 100 of FIG. 1, but this disclosure is not limited thereto.

In Step S200, a system sends the reset signal S1 to the memory storage apparatus 100, wherein the system is, for example, a processing circuit of a host system. In Step S210, the controller circuit 120 receives the reset signal S1. Next, in Step S220, the processing circuit judges whether the data stored in the memory array 110 needs to be maintained.

If the data stored in the memory array 110 needs to be maintained, the method flow will enter Step S230. In Step S230, the system sends the reset signal S1 and the trigger signal S2 to the memory storage apparatus 100. Next, in Step S240, the controller circuit 120 maintains the power supply to the memory array 110 according to the trigger signal S2 during the reset period T1. In Step S250, the controller circuit 120 performs the self-refresh operation on the memory array 110 during the self-refresh period T2. In Step S260, the controller circuit 120 stops performing the self-refresh operation on the memory array 110 according to the reference signal CKE.

On the other hand, if the data stored in the memory array 110 does not need to be maintained, the method flow will enter Step S270. In Step S270, the controller circuit 120 executes the reset operation, but does not continuously supply power to the memory array 110.

In summary, in the embodiments of this disclosure, the memory storage apparatus may perform reset without power outage, so the stored data may be retained after reset. In this way, the memory storage apparatus may be booted quickly, reducing interruption time and quickly restoring to the original state, which make it less likely for the user to feel that an abnormality has occurred.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A memory storage apparatus, comprising:
a memory array, configured to store data; and
a controller circuit, coupled to the memory array and configured to receive a reset signal and a trigger signal, wherein the controller circuit performs a reset operation according to the reset signal, and the controller circuit maintains a power supply to the memory array according to the trigger signal during a reset period.

2. The memory storage apparatus according to claim 1, wherein the controller circuit performs a self-refresh operation on the memory array after executing the reset operation.

3. The memory storage apparatus according to claim 2, wherein the controller circuit stops the self-refresh operation according to a reference signal.

4. The memory storage apparatus according to claim 2, wherein the controller circuit performs the self-refresh operation on the memory array after the reset period is greater than a preset time length.

5. The memory storage apparatus according to claim 1, wherein the trigger signal is a combination of an external signal input to a pin of the memory storage apparatus.

6. The memory storage apparatus according to claim 5, wherein the combination of the external signal comprises signal type or voltage level.

7. The memory storage apparatus according to claim 1, wherein the reset signal is used as the trigger signal, and a time length of the reset signal is used to determine whether to trigger an operation of maintaining the power supply to the memory array during the reset period.

8. The memory storage apparatus according to claim 1, further comprising:
a power supply circuit, coupled to the memory array and the controller circuit, and configured to provide a power supply to the memory array during the reset period, wherein the power supply circuit determines whether to maintain the power supply to the memory array during the reset period according to a command of the controller circuit.

9. A method for operating a memory storage apparatus, wherein the memory storage apparatus comprises a memory array, the method for operating comprising:
receiving a reset signal and a trigger signal;
performing a reset operation according to the reset signal; and
maintaining a power supply to the memory array according to the trigger signal during a reset period.

10. The method for operating the memory storage apparatus according to claim 9, further comprising performing a self-refresh operation on the memory array after executing the reset operation.

11. The method for operating the memory storage apparatus according to claim 10, further comprising stopping the self-refresh operation according to a reference signal.

12. The method for operating the memory storage apparatus according to claim 10, wherein the self-refresh operation is performed on the memory array after the reset period is greater than a preset time length.

13. The method for operating the memory storage apparatus according to claim 9, wherein the trigger signal is a combination of an external signal input to a pin of the memory storage apparatus.

14. The method for operating the memory storage apparatus according to claim 13, wherein the combination of the external signal comprises signal type or voltage level.

15. The method for operating the memory storage apparatus according to claim 9, wherein the reset signal is used as the trigger signal, and a time length of the reset signal is used to determine whether to trigger an operation of maintaining the power supply to the memory array during the reset period.
